(19) United States
(12) Patent Application Publication
(10) Pub. No.: US 2025/0224682 A1
(43) Pub. Date: Jul. 10, 2025

(54) COMPOSITION FOR REMOVING EDGE BEAD FROM METAL CONTAINING RESISTS, DEVELOPER COMPOSITION OF METAL CONTAINING RESISTS AND METHOD OF FORMING PATTERNS USING THE COMPOSITION

(71) Applicant: SAMSUNG SDI CO., LTD., Yongin-si (KR)

(72) Inventors: Jin-Hee BAE, Suwon-si (KR); Hyungrang MOON, Suwon-si (KR); Taeho KIM, Suwon-si (KR); Seung HAN, Suwon-si (KR); Jongpil HO, Suwon-si (KR); Myoungsoo SONG, Suwon-si (KR)

(21) Appl. No.: 18/954,286

(22) Filed: Nov. 20, 2024

(30) Foreign Application Priority Data
Jan. 8, 2024 (KR) 10-2024-0003041

(51) Int. Cl. G03F 7/32; G03F 7/004; G03F 7/42

(52) U.S. Cl. CPC G03F 7/325; G03F 7/0043; G03F 7/426

(57) ABSTRACT

A composition for removing edge beads from metal-containing resists or a developer composition of metal-containing resists, and a method of forming patterns using the same are provided. The composition includes a C3 to C20 aliphatic hydrocarbon compound substituted with at least two carboxyl groups; a mono-carboxylic acid compound; and an organic solvent.

### CROSS-REFERENCE TO RELATED APPLICATION

The present application claims priority to and the benefit of Korean Patent Application No. 10-2024-0003041, filed on Jan. 8, 2024, in the Korean Intellectual Property Office, the entire content of which is incorporated herein by reference.

### BACKGROUND

### 1. Field

This disclosure relates to compositions for removing edge beads from metal-containing resists or developer compositions of metal-containing resists, and methods of forming patterns using the same.

### 2. Description of the Related Art

In recent years, the semiconductor industry has been accompanied by (e.g., has seen) a substantially continuous reduction of critical dimensions (CD), and this dimensional reduction requires new types (kinds) of high-performance photoresist materials and a patterning method that satisfy a demand or desire for processing and patterning with increasingly smaller features.

In addition, with the recent rapid development of the semiconductor industry, a semiconductor device is desired or required to have a fast operation speed and large storage capacity, and in line with this requirement, process technology for improving integration, reliability, and a response speed of the semiconductor device is being developed or pursued. For example, it is important or desirable to accurately control/implant impurities in working regions of a silicon substrate and to interconnect these regions to form a device and/or an ultra-high-density integrated circuit, which may be achieved by a photolithographic process. For example, it is important or desirable to integrate the photolithographic process including coating a photoresist on the substrate, selectively exposing it to ultraviolet (UV) (including extreme ultraviolet (EUV)) light(s), electron beam(s), X ray(s), and/or the like, and then, developing it.

For example, in the process of forming the photoresist layer, while rotating the silicon substrate, the resist is mainly coated on (e.g., a top surface of) the substrate, but the resist may also be coated on an edge and rear surface of the substrate, which may generate particles and/or cause pattern defects in the subsequent semiconductor processes such as etching and/or ion implantation processes. Accordingly, a process of stripping and removing the photoresist coated on the edge and rear surface of the silicon substrate by using a thinner composition, that is, an edge bead removal (EBR) process is performed. The EBR process requires or desires a composition that exhibits excellent or suitable solubility for the photoresist and effectively removes beads and the photoresist remaining on the substrate (e.g., on the edge and rear surface of the substrate) and generates no or substantially no resist residue (i.e., without leaving any or substantially no resist residue).

There is a need or desire to develop a photoresist that can ensure excellent or suitable etch resistance and resolution in the photolithography process, while also improving sensitivity and critical dimension (CD) uniformity, as while as enhancing (i.e., improving) line edge roughness (LER) characteristics, and a developer composition that can implement these needed or desired features.

### SUMMARY

Aspects according to one or more embodiments are directed toward a composition for removing edge beads from metal-containing resists and/or a developer composition of metal-containing resists.

An aspect according to one or more embodiments is directed toward a method of forming patterns using the composition.

Additional aspects will be set forth in part in the description which follows and, in part, will be apparent from the description, or may be learned by practice of the presented embodiments of the disclosure.

According to one or more embodiments, a solvent-based composition includes a C3 to C20 aliphatic hydrocarbon compound substituted with at least two carboxyl groups; a mono-carboxylic acid compound; and an organic solvent, wherein the solvent-based composition is for removing edge beads from metal-containing resists or is a developer composition for metal-containing resists.

A method of forming patterns according to one or more embodiments includes coating a metal-containing photoresist composition on a substrate; coating an edge bead removing composition for removing edge beads from metal-containing resists along an edge of the substrate to remove a metal-containing resist edge bead; drying and heating to form a metal-containing photoresist layer on the substrate; exposing the metal-containing photoresist layer; and developing the metal-containing photoresist layer using a developer composition for metal-containing resists,
wherein at least one of the edge bead removing composition for removing edge beads from metal-containing resists or the developer composition for metal-containing resists includes the aforementioned solvent-based composition.

The composition (e.g., the edge bead removing composition) for removing edge beads from the metal-containing resists according to one or more embodiments reduces the metal-based contamination inherent in the metal-containing resists and removes the resist coated on the edge and the rear surface of the substrate, thereby satisfying requirements of processing and patterning of smaller features.

The developer composition for metal-containing resists according to one or more embodiments has improved cleaning power and stability over time, facilitates removal of a changed (e.g., reacted) photoresist region after an exposure process, and maintains removal performance for a long period of time. Thereby, excellent or suitable exposure characteristics (sensitivity, CD margin, line width roughness/line edge roughness (LWR/LER), etc.,) may be realized.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic view of a photoresist coating apparatus.

FIGS. 2 to 4 are cross-sectional views sequentially showing the process sequence of a method of forming patterns according to one or more embodiments of the present disclosure.

### DETAILED DESCRIPTION

Hereinafter, embodiments of the present disclosure are described in more detail with reference to the accompanying drawings. In the following description of the present disclosure, the known functions or constructions will not be described in order to clarify the present disclosure.

In order to clearly illustrate the present disclosure, the description and relationships that should be understood by those of ordinary skill in the art are not provided, and throughout the disclosure, the same or similar configuration elements are designated by the same reference numerals. Also, because the size and thickness of each configuration shown in the drawings are arbitrarily shown for better understanding and ease of description, the present disclosure is not necessarily limited thereto.

In the drawings, the thickness of layers, films, panels, regions, and/or the like, may be exaggerated for clarity. In the drawings, the thickness of a part of layers, regions, and/or the like, may be exaggerated for clarity. It will be understood that if (e.g., when) an element such as a layer, film, region, or substrate is referred to as being “on” another element, it can be directly on the other element or intervening elements may also be present.

In the present disclosure, the term “substituted” refers to replacement of a hydrogen atom by deuterium, a halogen, a hydroxyl group, a thiol group, a cyano group, a carbonyl group, a carboxyl group, an amino group, an amide group, an ester group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a C1 to C20 sulfide group. As used herein, the term “unsubstituted” refers to that a hydrogen atom remains as a hydrogen atom without being replaced by another substituent.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C5 alkyl group refers to that the alkyl chain contains 1 to 5 carbon atoms, and may be selected from among methyl, ethyl, propyl, iso-propyl, n-butyl, iso-butyl, sec-butyl, and t-butyl.

Specific non-limiting examples of the alkyl group include a methyl group, an ethyl group, a propyl group, an isopropyl group, a butyl group, an isobutyl group, a tert-butyl group, a pentyl group, a hexyl group, and/or the like.

In the chemical formulas described herein, “t-Bu” refers to a tert-butyl group.

In the present disclosure, if (e.g., when) a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

In the present disclosure, if (e.g., when) a definition is not otherwise provided, the term “heterocycloalkyl group” refers to a cycloalkyl group including at least one hetero atom selected from among N, O, S, P, and Si.

In the present disclosure, if (e.g., when) a definition is not otherwise provided, the term “alkenyl group” refers to a linear or branched aliphatic hydrocarbon group, and may refer to an aliphatic unsaturated alkenyl group containing one or more double bonds.

In the present disclosure, if (e.g., when) a definition is not otherwise provided, the term “alkynyl group” refers to a linear or branched aliphatic hydrocarbon group, and may refer to an unsaturated alkynyl group containing one or more triple bonds.

In the present disclosure, the term “aryl group” refers to a substituent in which all elements of a cyclic substituent have p-orbitals, and these p-orbitals form a conjugate and may include monocyclic or fused ring polycyclic (i.e., rings that share adjacent pairs of carbon atoms) functional groups.

For example, the term “a heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include one to three heteroatoms.

For example, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, and/or a (e.g., any suitable) combination thereof, but the present disclosure is not limited thereto.

For example, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, or a substituted or unsubstituted dibenzothiophenyl group, a substituted or unsubstituted benzonaphthofuranyl group, a substituted or unsubstituted benzonaphthothiophenyl group, a substituted or unsubstituted benzofuranofluorenyl group, a substituted or unsubstituted benzothiophenefluorenyl group, and/or a (e.g., any suitable) combination thereof, but the present disclosure is not limited thereto.

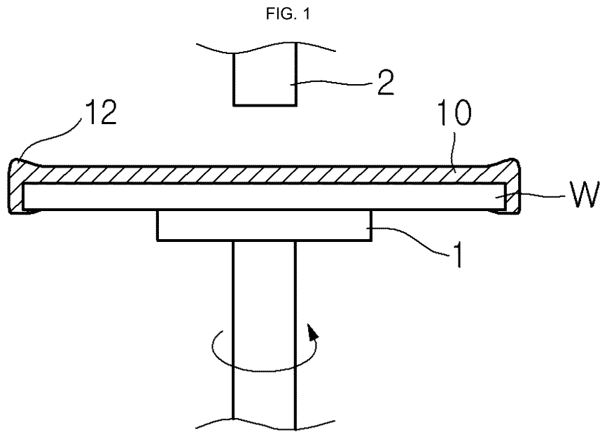

FIG. 1 is a schematic view showing the photoresist coating apparatus.

Referring to FIG. 1, a substrate support portion 1 on which a substrate W is placed is equipped therewith (e.g., within the photoresist coating apparatus), and the substrate support portion 1 includes a spin chuck or a spin coater.

The substrate support portion 1 rotates in a first direction at a set or predetermined rotation speed to provide a centrifugal force to the substrate W. A spray nozzle 2 may be positioned over (or on) the substrate support portion 1 but located off the upper portion of the substrate W in the atmospheric region (e.g., the spray nozzle 2 may be spaced and/or apart (e.g., spaced apart) from the upper surface of the substrate W) so that the spray nozzle may be moved toward the upper portion of the substrate W and spray a photoresist solution 10 in the spraying step (e.g., act or task). Accordingly, the photoresist solution 10 is coated on the surface of the substrate W by the centrifugal force. Herein, while the photoresist solution 10 supplied to the center of the substrate W is coated by spreading to the edge of the substrate W by the centrifugal force, a portion of the photoresist solution 10 moves to the side surfaces of the substrate W and the lower surface of the edge of the substrate.

For example, in the coating process, the photoresist solution 10 is coated (e.g., mainly) by a spin coating method, in which a set or predetermined amount of the photoresist solution 10 with (e.g., a suitable) viscosity is supplied to the center portion of the substrate W and gradually spreads toward the edge of the substrate W by the centrifugal force.

Accordingly, a photoresist layer is evenly formed through a rotational movement (e.g., speed) of the substrate support portion.

This rotation also evaporates a solvent from the solution (e.g., the photoresist solution 10) and thereby the viscosity thereof is gradually increased, resulting in a portion (e.g., a relatively large amount) of the photoresist accumulated on the edge of the substrate by the action of surface tension and even onto the lower surface of the edge of the substrate, which is referred to as edge beads 12. That is, the edge beads 12 refer to the photoresist accumulated on the edge portion of the substrate, including those on the top surface, the side surface and the bottom surface of the substrate.

Hereinafter, a composition (e.g., an edge bead removing composition) for removing edge beads from metal-containing resists and/or a developer composition of (or for) metal-containing resists according to one or more embodiments is described.

The composition for removing edge beads from metal-containing resists and/or developer composition of metal-containing resists according to one or more embodiments includes a C3 to C20 aliphatic hydrocarbon compound substituted with at least two carboxyl groups; a mono-carboxylic acid compound; and an organic solvent.

The C3 to C20 aliphatic hydrocarbon compound substituted with at least two carboxyl groups and the mono-carboxylic acid compound may be included at a weight ratio (the C3 to C20 aliphatic hydrocarbon compound substituted with at least two carboxyl groups:the mono-carboxylic acid compound) of about 1:0.01 to 1:2.

As an example, the C3 to C20 aliphatic hydrocarbon compound substituted with at least two carboxyl groups and the mono-carboxylic acid compound may be included in a weight ratio (the C3 to C20 aliphatic hydrocarbon compound substituted with at least two carboxyl groups:the mono-carboxylic acid compound) of about 1:0.1 to 1:2, about 1:0.1 to 1:1.5, about 1:0.2 to 1:1.5, about 1:0.3 to 1:1.5, or about 1:0.4 to 1:1.5.

By using a mixture of the C3 to C20 aliphatic hydrocarbon compound substituted with at least two carboxyl groups and the mono-carboxylic acid compound, the stability over time of the composition is improved and the cleaning power is increased, thereby minimizing or reducing various contaminant particles generated by a metal-containing photoresist on the edge or back of the substrate, facilitating the removal of changed (e.g., reacted) photoresist regions after the exposure process, and maintaining removal performance for a long period of time. Thereby, excellent or suitable exposure characteristics (sensitivity, CD margin, LWR/LER, etc.,) may be realized.

In the present specification, the carbon number of the C3 to C20 aliphatic hydrocarbon compound substituted with at least two carboxyl groups does not include carbon included in the carboxyl groups.

For example, in the case of the C3 aliphatic hydrocarbon compound substituted with at least two carboxyl groups, it refers to a structure in which at least two carboxyl groups are substituted on an aliphatic hydrocarbon having 3 carbon atoms.

In one or more embodiments, the C3 to C20 aliphatic hydrocarbon compound substituted with at least two carboxyl groups may be acyclic.

For example, the C3 to C20 aliphatic hydrocarbon compound substituted with at least two carboxyl groups may be represented by Chemical Formula 1.

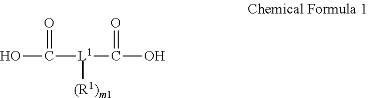

In Chemical Formula 1,
L¹ may be a substituted or unsubstituted C3 to C20 alkylene group, a substituted or unsubstituted C3 to C20 alkenylene group, a substituted or unsubstituted C3 to C20 alkynylene group, a C2 to C20 alkylene group substituted with at least one of a C1 to C10 aliphatic hydrocarbon group or a C6 to C12 aromatic hydrocarbon group, a C2 to C20 alkenylene group substituted with at least one of a C1 to C10 aliphatic hydrocarbon group or a C6 to C12 aromatic hydrocarbon group, a C3 to C20 alkynylene group substituted with at least one of a C1 to C10 aliphatic hydrocarbon group or a C6 to C12 aromatic hydrocarbon group, and/or a (e.g., any suitable) combination thereof,
R¹ may be an amine group, an amide group, a halogen group, a hydroxyl group, or a carboxyl group, and
m1 may be an integer of 0 or greater.

The upper limit of m1 may be a maximum value linkable to L¹, but m1 may be less than the maximum value, for example, from 1 to 10, 1 to 8, 1 to 6, or 1 to 3.

In one or more embodiments, L¹ may be a substituted or unsubstituted propylene, a substituted or unsubstituted butylene, a substituted or unsubstituted pentylene, a substituted or unsubstituted hexylene, a substituted or unsubstituted propenylene, a substituted or unsubstituted butenylene, a substituted or unsubstituted pentenylene, a substituted or unsubstituted hexenylene, an ethylene substituted with a C1 to C10 alkyl group, and/or a (e.g., any suitable) combination thereof.

For example, the C3 to C20 aliphatic hydrocarbon compound substituted with at least two carboxyl groups may be any one of (e.g., selected from among) the compounds listed in Group 1.

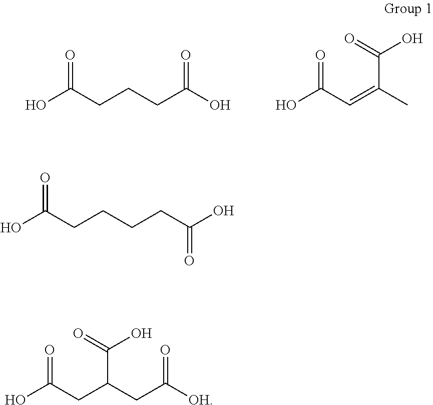

For example, the mono-carboxylic acid compound may be any one of (e.g., selected from among) the compounds listed in Group 2.

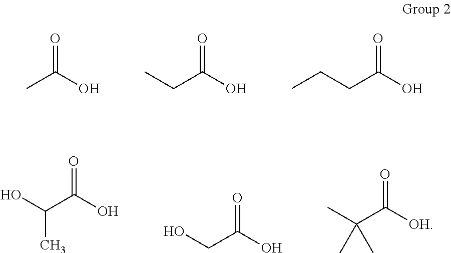

The C3 to C20 aliphatic hydrocarbon compound substituted with at least two carboxyl groups and the mono-carboxylic acid compound (e.g., together) may be included in an amount of about 0.1 wt % to about 30 wt % based on a total weight of the composition.

For example, the C3 to C20 aliphatic hydrocarbon compound substituted with at least two carboxyl groups and the mono-carboxylic acid compound may be included in an amount of about 0.1 wt % to about 25 wt % based on a total weight of the composition.

The composition for removing edge beads from metal-containing resists according to the present disclosure may be effective (e.g., particularly effective) in removing metal-containing resists, for example, undesirable metal residues, such as tin-based metal residues.

In addition, the developer composition of metal-containing resists according to the present disclosure minimizes or reduces defects present in the metal-containing photoresist layer after the exposure process and allows for easy development, thereby realizing excellent or suitable pattern characteristics.

In addition, excellent or suitable sensitivity and reduced line edge roughness (LER) can be achieved.

In some embodiments, one or more other additives (to be described in more detail later) may be included, and the organic solvent may be included in a balance amount excluding the other included components.

The one or more other additives may be selected from among a surfactant, a dispersant, a moisture absorbent, and a coupling agent.

According to some example embodiments, a method of forming patterns includes the step (e.g., act or task) of removing the edge beads using the aforementioned composition (e.g., edge bead removing composition) for removing edge beads from the metal-containing resist. For example, the manufactured pattern may be a photoresist pattern. For example, the manufactured pattern may be a negative-type or kind photoresist pattern.

A method of forming patterns according to one or more embodiments includes coating a metal-containing resist (e.g., photoresist) composition on a substrate, coating the aforementioned composition (e.g., edge bead removing composition) for removing edge beads from metal-containing resists along an edge of the substrate, drying and heating to form a metal-containing photoresist layer on the substrate, exposing the metal-containing photoresist layer, and developing the metal-containing photoresist layer.

For example, the forming of patterns using the metal-containing resist composition may include coating a metal-containing resist composition on a substrate (on which a thin film is formed) by spin coating, slit coating, inkjet printing, and/or the like, and drying the coated metal-containing resist composition to form a photoresist layer. The metal-containing resist composition may include a tin-based compound, and for example, the tin-based compound may include at least one of an organic oxy group or an organic carbonyloxy group.

For example, the metal-containing resist composition may include a metal compound represented by Chemical Formula 2.

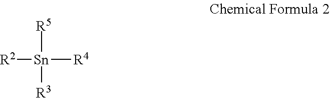

In Chemical Formula 2,
R² may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R³ to R⁵ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R^{b}, wherein R^{b} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (—NR^{c}R^{d}, wherein R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR^{e}(COR^{f}), wherein R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (—NR^{g}C(NR^{h})Rⁱ, wherein R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio or arylthiol group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or a thiocarboxyl group (—S(CO)R^{k}, wherein R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and
at least one selected from among R³ to R⁵ is selected from among an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R^{b}, wherein R^{b} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (—NR^{c}R^{d}, wherein R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR^{e}(COR^{f}), wherein R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (—NR^{g}C(NR^{h})Rⁱ, wherein R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio or arylthiol group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or a thiocarboxyl group (—S(CO)R^{k}, wherein R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

That is, at least one selected from among R³ to R⁵ is selected from among the alkoxy or aryloxy group represented by —OR^{a}, the carboxyl group represented by —O(CO)R^{b}, the alkylamido or dialkylamido group represented by —NR^{c}R^{d}, the amidato group represented by —NR^{e}(COR^{f}), the amidinato group represented by —NR^{g}C(NR^{h})Rⁱ, the alkylthio or arylthiol group represented by —SRI, and the thiocarboxyl group represented by —S(CO)R^{k}.

The metal compound included in the metal-containing resist composition may be represented by Chemical Formula 3 or Chemical Formula 4.

R⁶_{z}SnO_{(2-(z/2)-(x/2))}(OH)ₓ Chemical Formula 3

In Chemical Formula 3,

R⁶ may be a C1 to C31 hydrocarbyl group, 0<z≤2, and 0<(z+x)≤4;

R⁷ₙSnₘXₗYₖ Chemical Formula 4
wherein, in Chemical Formula 4,
R⁷ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, and/or a (e.g., any suitable) combination thereof,
X may be sulfur (S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof,
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof, and
n, m, l, and k may each independently be an integer of 1 to 20.

In one or more embodiments, the composition (e.g., edge bead removing composition) for removing edge beads from the metal-containing resists along the edge of the substrate may be coated while rotating the substrate at an appropriate or suitable speed (e.g., 500 rpm or more).

Subsequently, a first heat treatment process of heating the substrate on which the photoresist layer is formed is performed. The first heat treatment process may be performed at a temperature of about 80° C. to about 120° C. and in this process, the solvent is evaporated and the photoresist layer may be more firmly adhered to the substrate (i.e., during this process, the solvent evaporates, allowing the photoresist layer to adhere more firmly to the substrate).

Then, the photoresist layer is selectively exposed.

For example, examples of light that may be used in the exposure process may include not only light having a short wavelength such as i-line (wavelength 365 nm), KrF excimer laser (wavelength 248 nm), or ArF excimer laser (wavelength 193 nm), but also light having a high energy wavelength such as Extreme UltraViolet ((EUV), wavelength 13.5 nm), electron beam (E-beam), and/or the like.

In some embodiments, the light for exposure may be light having a wavelength range of about 5 nm to about 150 nm, and light having a high energy wavelength such as EUV (Extreme UltraViolet, wavelength 13.5 nm), E-Beam (electron beam), and/or the like.

In the step (e.g., act or task) of forming the photoresist pattern, a negative-type or kind pattern may be formed.

The exposed region of the photoresist layer has a solubility different from that of the unexposed region of the photoresist layer as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist layer becomes difficult to be dissolved in a developer.

For example, the photoresist pattern corresponding to the negative tone image may be completed by dissolving and removing the photoresist layer corresponding to the unexposed region using an organic solvent such as 2-heptanone.

Examples of the organic solvent included in the developer composition used in the method of forming patterns according to one or more embodiments may be, for example, one or more ketones such as methyl ethyl ketone, acetone, cyclohexanone, and/or 2-haptanone, alcohols such as 4-methyl-2-propanol, 1-butanol, isopropanol, 1-propanol, and/or methanol, esters such as propylene glycol monomethyl ether acetate, ethyl acetate, ethyl lactate, n-butyl acetate, butyrolactone, aromatic compounds such as benzene, xylene, and/or toluene, and/or a (e.g., any suitable) combination thereof.

The photoresist pattern (formed by exposure to not only light having a short wavelength such as i-line (wavelength 365 nm), KrF excimer laser (wavelength 248 nm), or ArF excimer laser (wavelength 193 nm), but also light having high energy such as EUV (Extreme UltraViolet, wavelength 13.5 nm), and/or exposure to an E-beam (electron beam)) may have a thickness (e.g., a thickness width) of about 5 nm to about 100 nm. That is, the photoresist pattern, formed by exposure to light with short wavelengths such as i-line (365 nm), KrF excimer laser (248 nm), ArF excimer laser (193 nm), or high-energy light like EUV (Extreme UltraViolet, 13.5 nm), or to even an E-beam (electron beam), may have a thickness of about 5 nm to about 100 nm. For example, the photoresist pattern may be formed to have a thickness (e.g., a thickness width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

Also, the photoresist pattern may have: a pitch (the distance between two identical points in adjacent patterns) with a half-pitch (half the distance between the two identical patterns) of less than or equal to about 50 nm, for example, less than or equal to 40 nm, less than or equal to 30 nm, less than or equal to 20 nm, or less than or equal to 15 nm; and a line width roughness of less than or equal to about 10 nm, for example, less than or equal to about 5 nm, less than or equal to about 3 nm, or less than or equal to about 2 nm.

A method of forming patterns according to one or more embodiments includes coating a metal-containing photoresist composition on a substrate, removing edge beads of the metal-containing photoresists, drying and heating to form a metal-containing photoresist layer on the substrate, exposing the metal-containing photoresist layer, and developing using the aforementioned developer composition of metal-containing resists.

The coating of the metal-containing resist composition on a substrate is the same as described above.

The removing of edge beads of the metal-containing resists may be performed by coating an appropriate or suitable amount of a suitable (e.g., generally known) organic solvent or composition for removing edge beads along the edge of the substrate while spinning the substrate at an appropriate or suitable speed (e.g., 500 rpm or more).

The drying and heating to form a metal-containing photoresist layer on the substrate is the same as described above.

The exposing of the metal-containing photoresist layer is the same as described above.

The photoresist pattern corresponding to the negative tone image may be completed by dissolving the photoresist layer corresponding to the unexposed region using the aforementioned developer composition of metal-containing resists and then removing the photoresist layer.

Specific non-limiting examples of the metal compound included in the metal-containing resist composition are as described above.

Hereinafter, a method of forming patterns by development is described in more detail with reference to the drawings.

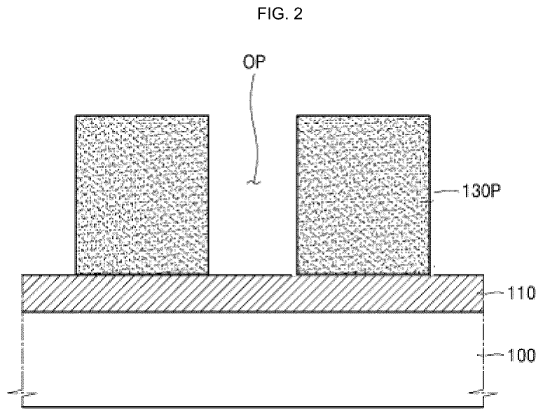

FIGS. 2 to 4 are cross-sectional views illustrating a process sequence in order to explain a method of forming patterns.

Referring to FIG. 2, the exposed photoresist layer (e.g., coated on the substrate 100) is developed to form a photoresist pattern 130P.

In one or more embodiments, the exposed photoresist layer may be developed to remove an unexposed region of the photoresist layer, and the photoresist pattern 130P including the exposed region of the photoresist layer may be formed. The photoresist pattern 130P may include a plurality of openings OP.

In one or more embodiments, the development of the photoresist layer may be performed through a negative-tone development (NTD) process. Herein, the developer composition (e.g., metal-containing photoresist developer composition) according to one or more embodiments may be used as a developer composition.

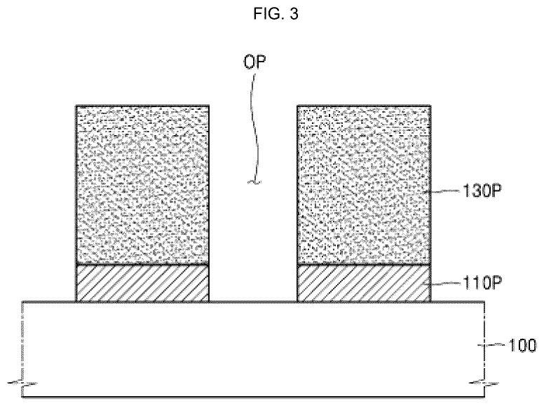

Referring to FIG. 3, the photoresist pattern 130P is used to process a feature layer (e.g., target layer) 110 from the result shown in FIG. 2.

For example, the feature layer 110 is processed through one or more suitable processes of etching the feature layer 110 exposed through the openings OP of the photoresist pattern 130P, injecting impurity ions into the feature layer 110, forming an additional film on the feature layer 110 through the openings OP, deforming (e.g., removing) a portion of the feature layer 110 through the openings OP, and/or the like. FIG. 3 illustrates an example process of processing a feature pattern 110P by etching the feature layer 110 exposed through the openings OP.

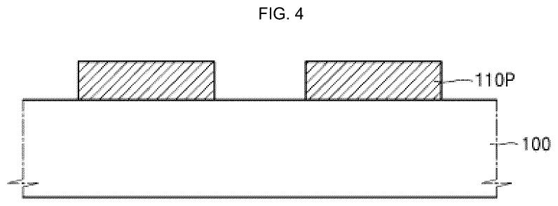

Referring to FIG. 4, the photoresist pattern 130P remaining on the feature pattern 110P in the result shown in FIG. 3 is removed. In order to remove the photoresist pattern 130P, an ashing and stripping process may be used.

A method of forming patterns according to one or more embodiments includes coating a metal-containing resist composition on a substrate, coating the aforementioned composition (e.g., edge bead removing composition) for removing edge beads from metal-containing resists along an edge of the substrate, drying and heating to form a metal-containing photoresist layer on the substrate, exposing the metal-containing photoresist layer, and developing the metal-containing photoresist layer using the aforementioned developer composition of metal-containing resists.

Each step (e.g., act or task) of the method is substantially the same as described above, but in the removing step (e.g., act or task) of edge beads and the developing step (e.g., act or task), the composition (e.g., edge bead removing composition) for removing edge beads from metal-containing resists and the developer composition of metal-containing resists according to embodiments of the present disclosure are concurrently (e.g., simultaneously) used to effectively improve an effect of removing the edge beads and solubility of the unexposed region and thus satisfying needs or desires for processing and patterning of smaller features, resultantly realizing excellent or suitable contrast characteristics, excellent or suitable sensitivity, and reduced line edge roughness (LER).

Hereinafter, the present disclosure will be described in more detail through examples relating to the preparation of the aforementioned composition for removing edge beads from metal-containing resists and developer composition of metal-containing resists. However, the technical features of the present disclosure are not limited by the following examples.

Preparation of Composition for Removing Edge Beads from Metal-Containing Resists/Developer Composition

### Example 1

Glutaric acid and propionic acid were mixed with propylene glycol methyl ether acetate (PGMEA) as a solvent according to the composition shown in Table 1 and then, completely dissolved therein by shaking at room temperature (25° C.). Subsequently, the obtained solution was filtered with an UPE filter material with a pore size of 0.01 μm to obtain a final composition.

### Examples 2 to 7 and Comparative Examples 1 to 5

Each composition was prepared in substantially the same manner as in Example 1 except that the composition was changed into each corresponding composition shown in Table 1.

TABLE 1

| | Developer composition | | |
|---|---|---|---|
| | Multi- | Mono- | |
| | carboxylic acid | carboxylic acid | Solvent |
| | (wt %) | (wt %) | (wt %) |
| Example 1 | Glutaric acid | Propionic acid | PGMEA |
| | (2.0) | (1.0) | (97.0) |
| Example 2 | Glutaric acid | Propionic acid | PGMEA |
| | (2.0) | (2.0) | (96.0) |
| Example 3 | citraconic acid | Acetic acid | PGMEA |
| | (2.0) | (1.0) | (97.0) |
| Example 4 | citraconic acid | Acetic acid | PGMEA |
| | (2.0) | (3.0 | (95.0) |
| Example 5 | Adipic acid | Butyric acid | PGMEA |
| | (2.0) | (1.0) | (97.0) |
| Example 6 | Adipic acid | Butyric acid | PGMEA |
| | (17.0) | (8.0) | (75.0 |
| Example 7 | Propane-1,2,3- | Propionic acid | PGMEA |
| | tricarboxylic acid | (1.0) | (97.0) |
| | (2.0) | | |
| Comparative | Tartaric acid | Acetic acid | PGMEA |
| Example 1 | (2.0) | (1.0) | (97.0) |
| Comparative | Dihydroxyfumaric acid | Butyric acid | PGMEA |
| Example 2 | (2.0) | (1.0) | (97.0) |
| Comparative | Malic acid | Acetic acid | PGMEA |
| Example 3 | (2.0) | (1.0) | (97.0) |
| Comparative | Glutaric acid | — | PGMEA |
| Example 4 | (2.0) | | (98.0) |
| Comparative | — | Propionic acid | PGMEA |
| Example 5 | | (2.0) | (98.0) |

### Preparation of Metal-Containing Photoresist Composition

A metal-containing compound having a structural unit of Chemical Formula C was dissolved in propylene-glycol-methyl-ether-acetate (PGMEA) at a concentration of 3 wt % and then, filtered with a 0.01 μm UPE filter, thereby preparing a photoresist composition.

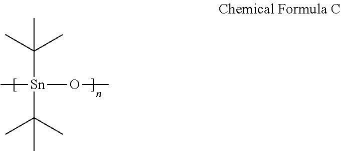

### Evaluation 1: Evaluation of Sn Residual Amount

1.0 mL of the photoresist compositions according to the preparation example was placed onto an 8-inch silicon wafer, allowed to stand for 20 seconds, and spin-coated at 1,500 rpm for 30 seconds to thereby prepare a wafer with a photoresist layer formed. Subsequently, 6.5 mL of each developer composition shown in Table 1 was added onto a respective wafer on which the photoresist layer was formed, allowed to stand for 20 seconds, and spin-dried (e.g., spin coated and/or dried) at 2,000 rpm for 30 seconds. The above process of adding the developer composition, allowing it to stand and spin-drying it was repeated 3 times. The obtained wafer was baked at 150° C. for 60 seconds and then, subjected to vapor phase decomposition inductively coupled plasma-mass spectrometry (VPD ICP-MS) analysis to confirm an Sn content (e.g., amount).

### Evaluation 2: Evaluation of Room Temperature Storage

Each developer composition described in Table 1 was stored at room temperature for 3 months and then, subjected to the VPD ICP-MS analysis to analyzed a residual Sn content (e.g., amount). In addition, a total amount of a carboxylic acid compound (e.g., a total content of a multi-carboxylic acid and a mono-carboxylic acid) before/after the storage was checked through gas chromatography (GC) analysis, and a moisture content (e.g., amount) before/after the storage was checked through Karl-fisher measurement.

A ratio of a content (e.g., amount) after the storage to a content (e.g., amount) before the storage was used to evaluate room temperature storage stability.

TABLE 2

| | | 3-month storage evaluation | | |
|---|---|---|---|---|
| | | Residual | a total | |
| | | Sn amount | amount of a | |
| | Residual | after 3 | carboxylic | |
| | Sn amount | months | acid compound | Moisture |
| | (×10¹⁰ | (×10¹⁰ | ratio after 3 | ratio after 3 |
| | atoms/cm²) | atoms/cm²) | months (%) | months (%) |
| Example 1 | 8700 | 8400 | 101 | 98 |
| Example 2 | 8100 | 8210 | 98 | 97 |
| Example 3 | 11000 | 11600 | 99 | 94 |
| Example 4 | 12100 | 11400 | 99 | 96 |
| Example 5 | 9200 | 9300 | 100 | 96 |
| Example 6 | 7700 | 8400 | 88 | 91 |
| Example 7 | 12100 | 12000 | 102 | 94 |
| Comparative | 45000 | 46000 | 47 | 77 |
| Example 1 | | | | |
| Comparative | 36000 | 37500 | 55 | 72 |
| Example 2 | | | | |
| Comparative | 40000 | 41500 | 72 | 82 |
| Example 3 | | | | |
| Comparative | 33000 | 31100 | 99 | 97 |
| Example 4 | | | | |
| Comparative | 39600 | 42300 | 99 | 100 |
| Example 5 | | | | |

Referring to Table 2, the metal-containing photoresist developer compositions according to the examples, compared with the metal-containing photoresist developer compositions according to the comparative examples, each exhibited stable and excellent or suitable development performance without (or with much less) room temperature storage changes in the residual Sn content (e.g., amount), the total amount of a carboxylic acid compound, and the moisture content (e.g., amount) and maintained development performance for a long time. That is, the metal-containing photoresist developer compositions from the examples, compared to those from the comparative examples, each exhibited stable and excellent development performance with minimal or little changes in residual Sn content, the total amount of a carboxylic acid compound, and moisture content during room temperature storage. These compositions maintained their development performance over an extended period. These characteristics of the compositions, when applied to the process, reduced metal-based contamination inherent in a metal-containing photoresist and thereby, realized finer pattern formation and excellent or suitable exposure characteristics (sensitivity, CD margin, LWR/LER, etc.). That is, when applied to the process, these characteristics reduced metal-based contamination inherent in metal-containing photoresists, enabling finer pattern formation and excellent exposure characteristics, such as sensitivity, CD margin, and/or LWR/LER.

The use of “may” when describing embodiments of the inventive concept refers to “one or more embodiments of the inventive concept.” It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. As used herein, the term “combination thereof” refers to a mixture, a laminate, a composite, a copolymer, an alloy, a blend, a reaction product, and/or the like of the constituents.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinbefore, the certain embodiments of the present disclosure have been described and illustrated, however, it is apparent to a person with ordinary skill in the art that the present disclosure is not limited to one or more embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Reference Numerals

| | |
|---|---|
| 1: substrate support portion | 2: spray nozzle |
| 10: photoresist solution | 12: edge bead |
| 100: substrate | OP: opening |
| 110: feature layer | |
| 110P: feature pattern | 130P: photoresist pattern |

What is claimed is:

1. A solvent-based composition comprising:
a C3 to C20 aliphatic hydrocarbon compound substituted with at least two carboxyl groups;
a mono-carboxylic acid compound; and
an organic solvent,
wherein the solvent-based composition is a composition for removing edge beads from metal-containing resists or a developer composition for metal-containing resists.

2. The solvent-based composition as claimed in claim 1, wherein
a weight ratio between the C3 to C20 aliphatic hydrocarbon compound substituted with at least two carboxyl groups and the mono-carboxylic acid compound is about 1:0.01 to about 1:2.

3. The solvent-based composition as claimed in claim 1, wherein
the C3 to C20 aliphatic hydrocarbon compound substituted with at least two carboxyl groups is acyclic.

4. The solvent-based composition as claimed in claim 1, wherein
the C3 to C20 aliphatic hydrocarbon compound substituted with at least two carboxyl groups is represented by Chemical Formula 1: 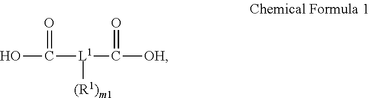
wherein, in Chemical Formula 1,
L¹ is
a substituted or unsubstituted C3 to C20 alkylene group,
a substituted or unsubstituted C3 to C20 alkenylene group,
a substituted or unsubstituted C3 to C20 alkynylene group,
a C2 to C20 alkylene group substituted with at least one of a C1 to C10 aliphatic hydrocarbon group or a C6 to C12 aromatic hydrocarbon group,
a C2 to C20 alkenylene group substituted with at least one of a C1 to C10 aliphatic hydrocarbon group or a C6 to C12 aromatic hydrocarbon group,
a C3 to C20 alkynylene group substituted with at least one of a C1 to C10 aliphatic hydrocarbon group or a C6 to C12 aromatic hydrocarbon group, or
a combination thereof,
R¹ is an amine group, an amide group, a halogen group, a hydroxy group, or a carboxyl group, and
m1 is an integer of 0 or greater.

5. The solvent-based composition as claimed in claim 4, wherein
L¹ is a substituted or unsubstituted propylene, a substituted or unsubstituted butylene, a substituted or unsubstituted pentylene, a substituted or unsubstituted hexylene, a substituted or unsubstituted propenylene, a substituted or unsubstituted butenylene, a substituted or unsubstituted pentenylene, a substituted or unsubstituted hexenylene, an ethylene substituted with a C1 to C10 alkyl group, or a combination thereof.

6. The solvent-based composition as claimed in claim 1, wherein
the C3 to C20 aliphatic hydrocarbon compound substituted with at least two carboxyl groups is any one selected from among compounds in Group 1:

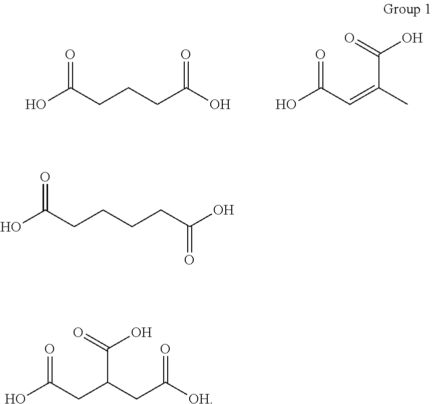

7. The solvent-based composition as claimed in claim 1, wherein
the mono-carboxylic acid compound is any one selected from among compounds in Group 2:

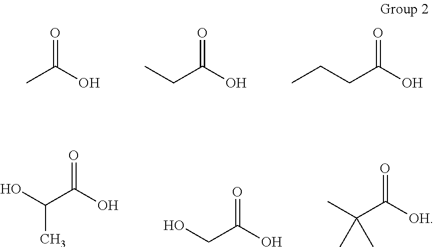

8. The solvent-based composition as claimed in claim 1, wherein
the C3 to C20 aliphatic hydrocarbon compound substituted with at least two carboxyl groups and the mono-carboxylic acid compound together are about 0.1 wt % to about 30 wt % in amount based on a total weight of the composition.

9. The solvent-based composition as claimed in claim 1, wherein
the C3 to C20 aliphatic hydrocarbon compound substituted with at least two carboxyl groups and the mono-carboxylic acid compound together are about 0.1 wt % to about 25 wt % based on a total weight of the composition.

10. A method of forming patterns, the method comprising:
coating a metal-containing photoresist composition on a substrate;
coating an edge bead removing composition for removing edge beads from metal-containing resists along an edge of the substrate to remove an edge bead;
drying and heating to form a metal-containing photoresist layer on the substrate;
exposing the metal-containing photoresist layer; and
developing the metal-containing photoresist layer utilizing a developer composition for metal-containing resists,
wherein at least one of the edge bead removing composition or the developer composition is the solvent-based composition as claimed in claim 1.

11. The method as claimed in claim 10, wherein
the metal-containing photoresist composition comprises a metal compound, and
the metal compound comprises at least one of an organic oxy group or an organic carbonyloxy group.

12. The method as claimed in claim 10, wherein
the metal-containing photoresist composition comprises a metal compound represented by Chemical Formula 2: 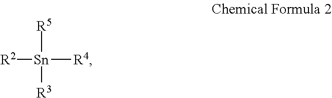
wherein, in Chemical Formula 2,
R² is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R³ to R⁵ are each independently:
a substituted or unsubstituted C1 to C20 alkyl group;
a substituted or unsubstituted C3 to C20 cycloalkyl group;
a substituted or unsubstituted C2 to C20 alkenyl group;
a substituted or unsubstituted C2 to C20 alkynyl group;
a substituted or unsubstituted C6 to C30 aryl group;
a substituted or unsubstituted C6 to C30 arylalkyl group;
an alkoxy or aryloxy group represented by —OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof;
a carboxyl group represented by —O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof;
an alkylamido or dialkylamido group represented by —NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof;
an amidato group represented by —NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof;
an amidinato group represented by —NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof;
an alkylthio or arylthiol group represented by —SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; or
a thiocarboxyl group represented by —S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
at least one selected from among R³ to R⁵ is selected from among the alkoxy or aryloxy group represented by —OR^{a}, the carboxyl group represented by —O(CO)R^{b}, the alkylamido or dialkylamido group represented by —NR^{c}R^{d}, the amidato group represented by —NR^{e}(COR^{f}), the amidinato group represented by —NR^{g}C(NR^{h})Rⁱ, the alkylthio or arylthiol group represented by —SR^{j}, and the thiocarboxyl group represented by —S(CO)R^{k}.

13. The method as claimed in claim 10, wherein
the metal-containing photoresist composition comprises a metal compound represented by Chemical Formula 3 or Chemical Formula 4:
R⁶_{z}SnO_{(2-(z/2)-(x/2))}(OH)ₓ Chemical Formula 3
wherein, in Chemical Formula 3,
R⁶ is a C1 to C31 hydrocarbyl group, 0<z≤2, and 0<(z+x)≤4,
R⁷ₙSnₘXₗYₖ Chemical Formula 4
wherein, in Chemical Formula 4,
R⁷ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te),
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
n, m, l, and k are each independently an integer of 1 to 20.

14. A composition for removing edge beads from metal-containing resists being the solvent-based composition as claimed in claim 1.

15. A developer composition for metal-containing resists being the solvent-based composition as claimed in claim 1.

16. The method as claimed in claim 10, wherein
the edge bead removing composition is the solvent-based composition.

17. The method as claimed in claim 10, wherein
the developer composition is the solvent-based composition.

18. The method as claimed in claim 10, wherein
the edge bead removing composition and the developer composition are each the solvent-based composition.

19. A solvent-based composition comprising:
a C3 to C20 aliphatic hydrocarbon compound substituted with at least two carboxyl groups;
a mono-carboxylic acid compound; and
an organic solvent.

20. A method of forming patterns, the method comprising:
coating a metal-containing photoresist composition on a substrate;
coating an edge bead removing composition for removing edge beads from metal-containing resists along an edge of the substrate to remove an edge bead;
drying and heating to form a metal-containing photoresist layer on the substrate;
exposing the metal-containing photoresist layer; and
developing the metal-containing photoresist layer utilizing a developer composition for metal-containing resists,
wherein at least one of the edge bead removing composition or the developer composition is the solvent-based composition as claimed in claim 19.
